(19) United States
(12) Patent Application Publication
(10) Pub. No.: US 2025/0183891 A1
(43) Pub. Date: Jun. 5, 2025

(54) LINE DRIVERS FOR LOW-VOLTAGE SIGNALING BETWEEN DIFFERENT VOLTAGE DOMAINS

(71) Applicant: NVIDIA Corp., Santa Clara, CA (US)

(72) Inventor: Walker Joseph Turner, Jacksonville, FL (US)

(73) Assignee: NVIDIA Corp., Santa Clara, CA (US)

(21) Appl. No.: 18/527,921

(22) Filed: Dec. 4, 2023

(51) Int. Cl. H03K 17/687; H03K 17/06; H03K 19/00; H03K 19/0185

(52) U.S. Cl. CPC H03K 17/6872; H03K 17/063; H03K 19/0013; H03K 19/018521

(57) ABSTRACT

Line drivers for high-bandwidth wireline transceivers that utilize both NFET and PFET pull-up devices to reduce supply sensitivity of low-voltage signals that cross voltage domains, for example between chips. Also AC-coupled latching receivers for level translation and amplification in low-voltage wireline transceivers to reduce supply sensitivity of low-voltage signals that cross voltage domains, for example between chips.

### BACKGROUND

High-performance interconnects are utilized to communicate signals chip-to-chip in advanced computing applications, where integration of chips implemented in different technology nodes enables solutions for both 2.5D and 3D-stacked packages. The interconnects often cross supply voltage domains because different chips in a package may operate on different supply voltages. One example is a processor (using an advanced technology node operating on a low supply voltage) that communicates with a High-Bandwidth Memory (HBM) chip optimized to reduce bit cell leakage and thus having slower transistors operating on a higher supply than the processor.

Terminated links (herein also, “lines”) may be utilized in these circumstances to enable the use of smaller signal amplitudes on the line and thereby reduce dynamic line power. However the resulting DC line current may negatively impact energy efficiency at lower operating bandwidths and/or line activity.

Full-swing signaling at a lower supply voltage on un-terminated links may be utilized to minimize dynamic line power depending on channel characteristics and target data-rates. FIG. 1A depicts one conventional full-swing low-voltage line driver 102 circuit. The line driver 102 operates on a third regulated supply voltage (V_{IO}), which is nominally lower than the transmitter voltage domain supply voltage (V_{TX}). For example the line driver may operate at or near 0.4V and the transmitter supply voltage may be 0.75V, for example.

An N-over-N driver (wherein a stack of NFETs provides both a pull-up path on the line and a pull-down path on the line) drives the line full-swing between the third (line-specific) supply voltage V_{IO} and (nominally) 0V, operating as both the line driver and a level shifter between the V_{TX} and V_{IO} voltage domains. A pull-up path should be accorded its ordinary meaning in the art, that is, an electrical path to a supply rail. A pull-up transistor is a transistor providing a pull-up path controlled by a gate drive to the transistor. Likewise, a pull-down path provides an electrical path to a circuit ground (e.g., ‘VSS’ in common parlance), and a pull-down transistor implements a pull-down path via its gate drive.

A continuous-time (i.e., ‘analog’) amplifier is commonly used at the receiver to amplify the line voltage through comparison with a reference voltage (V_{REF}). However the amplifier DC current may negatively impact link efficiency.

A continuous-time amplifier is an electronic device designed to amplify continuous signals, such as analog audio or video signals, without any breaks or interruptions in the time domain. It functions by continuously amplifying the input signal in real time, without relying on discrete samples or a digitization process. This allows for the faithful reproduction of the original continuous signal waveform, maintaining its shape, amplitude, and frequency characteristics.

Alternatively, the line may be directly sampled by comparing the incoming signal with V_{REF}. This approach is incompatible with delay-matched clock forwarded architectures and requires additional timing circuits to maintain clock-to-data phase relationships across process, voltage, and temperature variations.

Clock forwarding in the context of high-speed links typically refers to sending (or forwarding) a clock from the transmitter to the receiver along with the data, to act as a timing reference. Once received, the clock is then distributed to the data receiver lanes, along with mechanisms to mitigate skew between the lanes. This helps enable data recovery on the receive end. With delay-matched clock forwarding, the end-to-end insertion delays (from transmitter to receiver) are matched for the data and clock signals, such that their voltage and temperature dependencies track.

For application where the receiver is implemented in a faster technology node with a lower supply voltage, the transceiver may be adapted to remove the utilization of a third supply voltage as depicted in FIG. 1B. The N-over-N line driver 102 operates on the receiver supply (V_{RX}), thus centering the line signal between V_{RX} and 0V and enabling the receiver to utilize an inverter-based amplifier.

The N-over-N line driver 102 produces asymmetric rise and fall times with a strong dependency on the NFET threshold voltage and the supply magnitudes (V_{TX} and V_{RX}). This calls for V_{TX} to be set much higher than V_{RX} to ensure sufficient gate over-drive for the pull-up device. This supply-dependent asymmetry translates into the rise/fall crossing point to occur at a value lower than V_{RX}/2, resulting in clock duty cycle distortion (DCD) and increased reference voltage trim requirements.

### BRIEF DESCRIPTION OF THE SEVERAL VIEWS OF THE DRAWINGS

To easily identify the discussion of any particular element or act, the most significant digit or digits in a reference number refer to the figure number in which that element is first introduced.

FIG. 1A depicts a conventional line driver circuit.

FIG. 1B depicts another conventional line driver circuit.

FIG. 2 depicts a transceiver utilizing a P-over-N line driver in accordance with one embodiment.

FIG. 3 depicts a transceiver utilizing a P-over-N line driver in accordance with another embodiment.

FIG. 4 depicts a transceiver utilizing a P-over-N line driver in accordance with another embodiment.

FIG. 5 depicts an embodiment of a transceiver in accordance with one embodiment.

FIG. 6 depicts an embodiment of a transceiver in accordance with another embodiment.

FIG. 7 depicts an embodiment of a transceiver in accordance with another embodiment.

FIG. 8 depicts an embodiment of a transceiver in accordance with another embodiment.

FIG. 9 depicts an embodiment of a transceiver in accordance with another embodiment.

FIG. 10 depicts an embodiment of a transceiver in accordance with another embodiment.

FIG. 11 depicts a parallel processing unit 1120 in accordance with one embodiment.

FIG. 12 illustrates an exemplary data center 1200 in accordance with one embodiment.

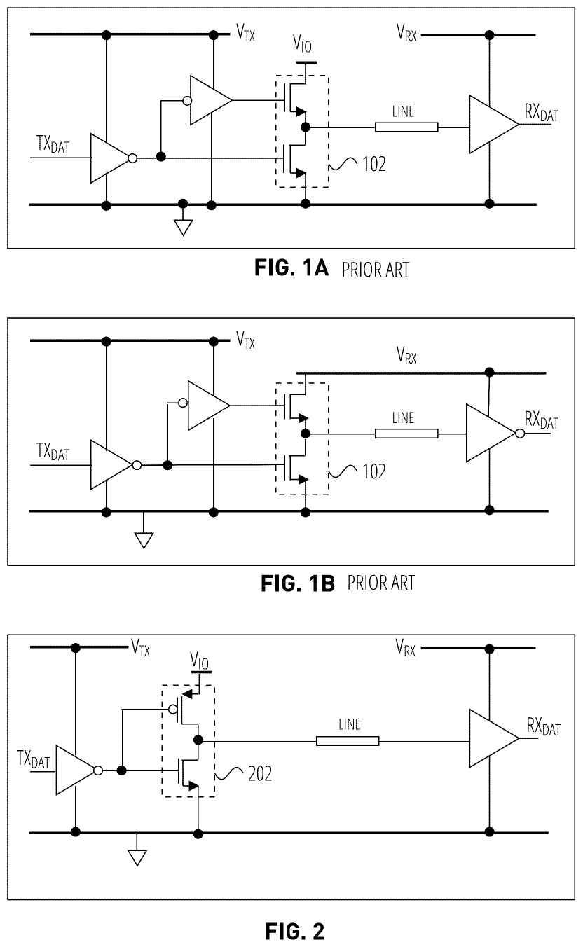

### DETAILED DESCRIPTION

Embodiments of a line driver are disclosed that utilize both NFET and PFET pull-up devices to reduce supply sensitivity in low-voltage wireline transceivers. Embodiments of an AC-coupled latching receiver are also disclosed for level translation and amplification in low-voltage wireline transceivers.

The transmitter of the transceiver may generate signals in a first voltage domain. A driver for the transmission line receives the signals from the transmitter and utilizes a P-over-N driver and a feed-forward pull-up transistor coupled to the first line to output the signals on the transmission line in a second voltage domain. The receiver of the transceiver is coupled to receive the signal in the second voltage domain, and may be configured to operate in the second voltage domain or in a third voltage domain. Herein, it should be understood that voltage domains described as first, second, third, and so on are each describing a different voltage range.

The line driver implements a PFET pull-up path and an NFET pull-up path arranged in parallel to a second voltage domain, and a feed-forward path for the signals configured to boost a transition of the signals from lower to higher voltage levels on the line. The following examples depict particular embodiments to implement this behavior, however variations in the structure and components of the circuit may be made by those of ordinary skill in the art that fall within the scope of the invention.

In transceiver embodiments implementing two-way communication, each end of the transmission lines may comprise both transmitters and receivers, and one end may comprise an inverter-based line driver coupled to a level shifter in the other end via one of the transmission lines. In these embodiments the level shifter may shift a voltage of the signals from the second voltage domain to the first voltage domain.

In some cases the transmission lines interface a first chip and a second chip. Other technical features of the above-described embodiments may be readily apparent without further elaboration to one skilled in the art from the following figures, descriptions, and claims.

Other embodiments may utilize AC-coupled links. One such embodiment of a transceiver circuit includes a transmitter in a first voltage domain that is AC-coupled to a receiver in a second voltage domain over the line, and a P-over-N driver (wherein a stack comprising a pull-up PFET transistor and a pull-down NFET transistor drive the signal on the line) configured to receive a signal in a first voltage domain of the transmitter, and to output the signal on the line. In one embodiment the transmitter comprises the P-over-N driver. The transmitter may comprise logic operating in the first voltage domain to drive the P-over-N driver. The receiver includes a pair of inverter stages arranged along the line, with negative feedback to a first inverter stage of the pair and positive feedback to both inverter stages. In this embodiment the transmitter may be AC-coupled to the receiver via a capacitor that is proximity biased toward the transmitter on the line.

Another AC-coupled embodiment utilizes a transmitter in comprising logic operating in a first domain that drives an N-over-N line driver operating in a third voltage domain, wherein the N-over-N line driver is AC-coupled over the line to a receiver operating in a second voltage domain. The N-over-N driver is configured to receive the signal in a first voltage domain of the transmitter. However, the N-over-N driver outputs the signal on the line in the third voltage domain in this embodiment. Again, the receiver includes a pair of inverter stages arranged along the line, with negative feedback to a first inverter stage of the pair and positive feedback to both inverter stages. In this embodiment, the transmitter may be AC-coupled to the receiver via a capacitor that is proximity biased toward the receiver on the line. Other technical features of these AC-coupled embodiments may be readily apparent without further elaboration to one skilled in the art from the following figures, descriptions, and claims.

FIG. 2 depicts a transceiver utilizing a P-over-N line driver 202 that operates in a voltage domain (V_{IO}) that is lower than the voltage domain (V_{TX}) in which the inverter-based transmitter operates and that is different than the voltage domain (V_{RX}) in which the receiver operates. This embodiment may exhibit unequal gate-to-source voltage magnitudes on the NFET and PFET devices of the P-over-N line driver 202, distorting the signal on the line, and the PFET drive strength is limited by the magnitude of V_{IO}, potentially operating near weak inversion.

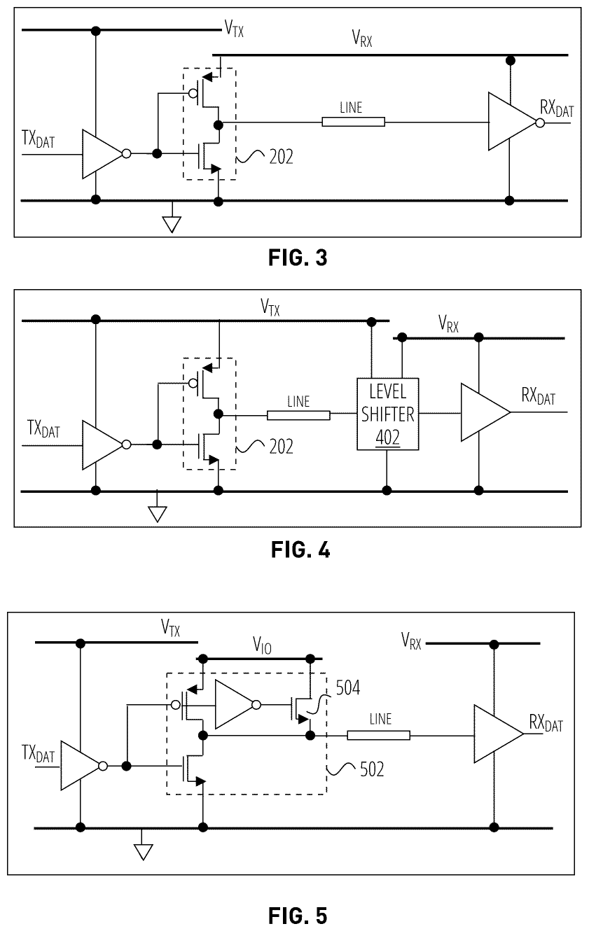

FIG. 3 depicts a transceiver utilizing a P-over-N line driver 202 that operates in the same voltage domain (V_{RX}) in which the receiver operates. The practical viability of this embodiments depends on the transmitter-side device characteristics and the V_{RX} magnitude. The voltage dependency of the drive strengths of the NFET and PFET devices are uncorrelated, where each varies with V_{TX} and V_{RX}, respectively, and which may result in undesirable operational behavior in the field.

FIG. 4 depicts a transceiver utilizing a P-over-N line driver 202 that operates in the same voltage domain (V_{TX}) in which the transmitter operates. The signals on the line are at the full-swing of V_{TX}, which increases dynamic line energy and calls for use of a level shifter 402 at the receiver. These factors may lead to voltage compliance complications and aging-related operating problems. Addressing these issues by utilizing thick-oxide devices increases the receiver circuit area, which is potentially problematic as 3D-stacking technologies progress to extremely dense input/output pitches (e.g., <3 μm) with improvements in die bonding technology.

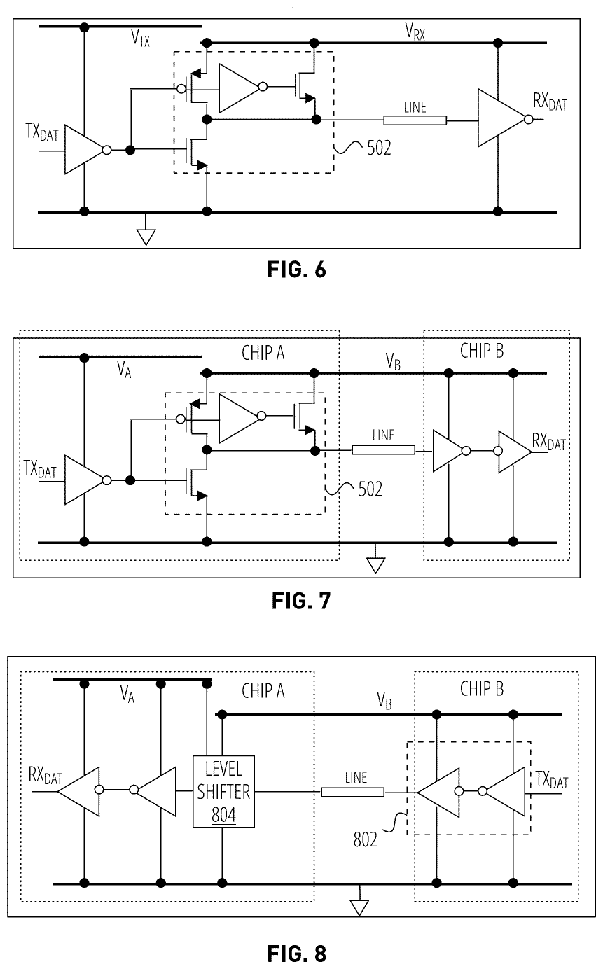

FIG. 5 depicts an embodiment of a line driver utilizing a line driver 502 operating in a voltage domain (V_{IO}) different from the transmitter voltage domain (V_{TX}) or the receiver voltage domain (V_{RX}). A line driver 502 with this structure may also operate from the receiver supply domain as depicted in FIG. 6.

The line driver 502 comprises a P-over-N driver on the line and a circuit structure that feeds the data signal from the transmitter forward to a pull-up transistor 504 on the line, bypassing the gate of the PFET of the P-over-N driver. In addition to the pull-up path provided by the feed-forward pull-up transistor 504, the PFET of the P-over-N driver provides a second pull-up path to the voltage domain of the line driver 502.

The P-over-N driver utilized in the line driver 502 is a sparse structure consisting of a pull-up path implemented by a single PFET and a pull-down path implemented by a single NFET, with the PFET and NFET connected at a common node to one another and to the line.

The embodiment depicted in FIG. 5 utilizes parallel PFET and NFET pull-up paths by way of a P-over-N driver and a feed-forward pull-up transistor coupled to the transmission line. This facilitates transitions of the line to the higher end of the line driver voltage domain range (V_{IO} in FIG. 5) facilitating transitions across a wider range of V_{TX}-to-V_{IO} ratios. The NFET pull-up transistor 504 and the PFET of the P-over-N driver trade drive strength across variations in V_{TX} and the driver supply (V_{IO}/V_{RX}). The NFET pull-up transistor 504 exhibits stronger drive strength at large V_{TX}-to-V_{IO} ratios, and the PFET exhibits drive strength comparable to the drive strength of the pull-down path at smaller V_{TX}-to-V_{IO} ratios.

A feed-forward signal path herein refers to a signal path from the transmitter that bypasses a portion of the line driver circuitry to forward the transmitter signal to a component farther down the signal propagation path on the line. The input signal is split into two paths. In the transceiver depicted in FIG. 5, one signal path from an inverter of the transmitter drives the PFET of the P-over-N driver, while another path bypasses the gates of the P-over-N driver to drive the pull-up transistor 504 farther down the line. A feed-forward pull-up transistor is a pull-up transistor such as pull-up transistor 504 that is driven by a feed-forward signal path.

In the line driver 502 embodiment, the feed-forward signal path comprises a single inverter with a size that approximately matches a size of the inverter utilized in the transmitter.

Operating the line driver 502 in the receiver supply voltage domain V_{RX}, as in FIG. 6, simplifies the circuit layout and may improve energy efficiency for some supply voltage and/or receiver configurations. In some implementations, it may be desirable to add a dummy PFET load to the feed-forward signal path that drives the pull-up transistor 504 to balance fanout of the complimentary signals.

FIG. 7 depicts an exemplary application of the line driver 502 on a half-duplex link between two chips (A and B), where chip A's supply voltage (V_{A}) is larger than chip B's supply voltage (V_{B}). Full-swing signaling is achieved on the lower supply voltage of chip B. For transmission of signals from A-to-B, the line driver 502 is used while the receiver is comprised solely of inverters along the line (herein, an ‘inverter-based’ topology). For B-to-A communication, FIG. 8, the line driver 802 is inverter-based and the chip A receiver uses a level shifter 804 to amplify and level shift the incoming signal into the V_{A} supply voltage domain.

The chip A level shifter 804 may amplify the incoming signal using inverters operating on the transmitter supply (V_{B}) to generate complimentary signals that toggle the state of cross-coupled PFETs or inverters operating on V_{A}. While this results in nominally zero (0) DC operating current, the viability of this mechanism in practice depends on the V_{B} magnitude, the device characteristics in chip A, link data-rate, and the incoming signal amplitude. For example this mechanism may be practical for Dynamic Random Access Memory (DRAM) technologies operating on supply voltages of 0.75V at data-rates of 2.5 Gb/s and below.

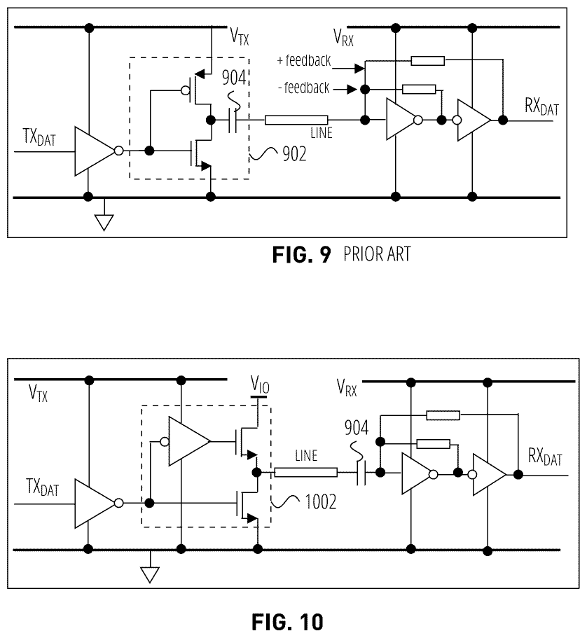

Other structures can also be used for the receiver in chip A, such as the continuous-time amplifying AC-coupling mechanisms described in conjunction with FIG. 9 and FIG. 10.

The line driver 502 may be designed to be configurable, where digital control bits may be applied to reconfigure the driver into a P-over-N driver, an N-over-N driver, or a hybrid of these two, based on the supply voltage of the chip it will be communicating with. The level-shifting receiver may also be reconfigured into an inverter-based receiver when operating both low-side/high-side voltages from the same potential (i.e. level translating between the same potential).

Operating the line driver in the voltage domain of a regulated supply different than the voltage domain of the transmitter or the receiver may call for voltage level shifting between the low-voltage line signal and the higher supply voltage of the receiver. This may be accomplished using a transconductance amplifier, a sampler, or a voltage level shifting circuit, for example.

An alternative mechanism utilizes an AC-coupled link with a pair of inverter stages in the receiver. The line driver 902 comprises a P-over-N driver and a capacitor 904 that is proximity biased to the transmitter (closer to the transmitter end of the transmission line than the receiver end of the transmission line). Negative feedback is applied across the first inverter stage and positive feedback is applied across both inverter stages, as depicted in the exemplary embodiment of FIG. 9. The negative feedback across the first inverter stage biases the input to the inverters in a range around the inverters' high-gain potential (nominally V_{RX}/2) while the positive feedback generates a latching mechanism by feeding a portion of the rail-to-rail (full-swing) signal output from the second stage (RX_{DAT}) back to the input terminal of the first inverter stage. This causes the input node from the line to the first inverter stage to settle above or below the inverter high-gain point based on the polarity of RX_{DAT}, where the DC amplitude at the input is determined by the ratio of the positive feedback resistance and the input impedance of the first stage inverter.

In the embodiment depicted in FIG. 9, the DC line signal amplitude is set by the receiver's feedback configuration, and the line driver 902 may inject signals that toggle the binary voltage level latched in the receiver. This type of structure may function well with industry-standard low-voltage drivers (i.e. N-over-N drivers) by AC-coupling the received signal to the input of the latching amplifier as in FIG. 10, with the capacitor 904 proximity biased to the receiver. This removes the need for conventional amplifier or level shifting structures by performing level translation through the receiver-side coupling capacitance. The coupling capacitor 904 should be sized to inject enough energy to toggle the receiver latch state based on the incoming signal amplitude from the line. The positive and negative feedback strengths may be set to achieve a desired DC or low-frequency amplitude at the receiver latch input. This structure also obviates the need to apply a reference voltage in the receiver as utilized by conventional amplifier-based and direct line sampling approaches.

The embodiment depicted in FIG. 10 utilizes an N-over-N driver with an AC-coupled receiver. Another embodiment utilizes a P-over-N driver (operating on VIO) with the AC-coupled receiver.

Transceivers in accordance with the embodiments disclosed herein may be utilized in computing devices comprising one or more graphic processing unit (GPU) and/or general purpose data processor (e.g., a ‘central processing unit or CPU). Exemplary computing architectures are described that may be configured with embodiments of the transceivers disclosed herein. For example, any two components of the exemplary system that operate in different voltage domains may communicate via embodiments of the transceivers disclosed herein.

The following description may use certain acronyms and abbreviations as follows:
“DPC” refers to a “data processing cluster”;
“GPC” refers to a “general processing cluster”;
“I/O” refers to a “input/output”;
“L1 cache” refers to “level one cache”;
“L2 cache” refers to “level two cache”;
“LSU” refers to a “load/store unit”;
“MMU” refers to a “memory management unit”;
“MPC” refers to an “M-pipe controller”;
“PPU” refers to a “parallel processing unit”;
“PROP” refers to a “pre-raster operations unit”;
“ROP” refers to a “raster operations”;
“SFU” refers to a “special function unit”;
“SM” refers to a “streaming multiprocessor”;
“Viewport SCC” refers to “viewport scale, cull, and clip”;
“WDX” refers to a “work distribution crossbar”; and
“XBar” refers to a “crossbar”.

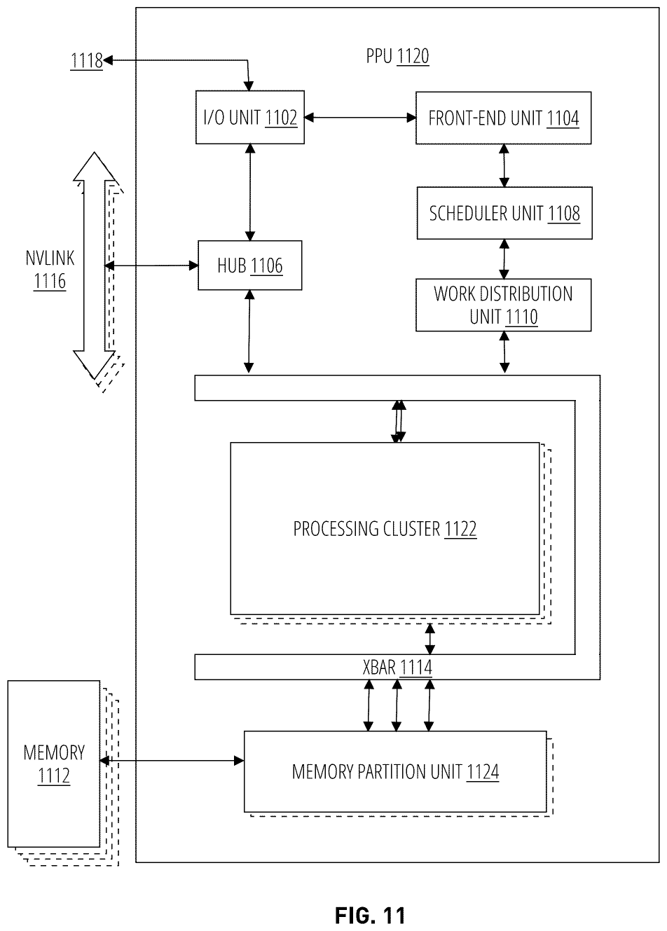

FIG. 11 depicts a parallel processing unit 1120, in accordance with an embodiment. In an embodiment, the parallel processing unit 1120 is a multi-threaded processor that is implemented on one or more integrated circuit devices. The parallel processing unit 1120 is a latency hiding architecture designed to process many threads in parallel. A thread (e.g., a thread of execution) is an instantiation of a set of instructions configured to be executed by the parallel processing unit 1120. In an embodiment, the parallel processing unit 1120 is a graphics processing unit (GPU) configured to implement a graphics rendering pipeline for processing three-dimensional (3D) graphics data in order to generate two-dimensional (2D) image data for display on a display device such as a liquid crystal display (LCD) device. In other embodiments, the parallel processing unit 1120 may be utilized for performing general-purpose computations. While one exemplary parallel processor is provided herein for illustrative purposes, it should be strongly noted that such processor is set forth for illustrative purposes only, and that any processor may be employed to supplement and/or substitute for the same.

One or more parallel processing unit 1120 modules may be configured to accelerate thousands of High Performance Computing (HPC), data center, and machine learning applications. The parallel processing unit 1120 may be configured to accelerate numerous deep learning systems and applications including autonomous vehicle platforms, deep learning, high-accuracy speech, image, and text recognition systems, intelligent video analytics, molecular simulations, drug discovery, disease diagnosis, weather forecasting, big data analytics, astronomy, molecular dynamics simulation, financial modeling, robotics, factory automation, real-time language translation, online search optimizations, and personalized user recommendations, and the like.

As shown in FIG. 11, the parallel processing unit 1120 includes an I/O unit 1102, a front-end unit 1104, a scheduler unit 1108, a work distribution unit 1110, a hub 1106, a crossbar 1114, one or more general processing cluster 1122 modules, and one or more memory partition unit 1124 modules. The parallel processing unit 1120 may be connected to a host processor or other parallel processing unit 1120 modules via one or more high-speed NVLink 1116 interconnects. The parallel processing unit 1120 may be connected to a host processor or other peripheral devices via an interconnect 1118. The parallel processing unit 1120 may also be connected to a local memory comprising a number of memory 1112 devices, for example using one or more of the transceiver embodiments disclosed herein. In an embodiment, the local memory may comprise a number of dynamic random access memory (DRAM) devices. The DRAM devices may be configured as a high-bandwidth memory (HBM) subsystem, with multiple DRAM dies stacked within each device. The memory 1112 may comprise logic to configure the parallel processing unit 1120 to carry out aspects of the techniques disclosed herein.

The NVLink 1116 interconnect enables systems to scale and include one or more parallel processing unit 1120 modules combined with one or more CPUs, supports cache coherence between the parallel processing unit 1120 modules and CPUs, and CPU mastering. Data and/or commands may be transmitted by the NVLink 1116 through the hub 1106 to/from other units of the parallel processing unit 1120 such as one or more copy engines, a video encoder, a video decoder, a power management unit, etc. (not explicitly shown).

The I/O unit 1102 is configured to transmit and receive communications (e.g., commands, data, etc.) from a host processor (not shown) over the interconnect 1118. The I/O unit 1102 may communicate with the host processor directly via the interconnect 1118 or through one or more intermediate devices such as a memory bridge. In an embodiment, the I/O unit 1102 may communicate with one or more other processors, such as one or more parallel processing unit 1120 modules via the interconnect 1118. In an embodiment, the I/O unit 1102 implements a Peripheral Component Interconnect Express (PCIe) interface for communications over a PCIe bus and the interconnect 1118 is a PCIe bus. In alternative embodiments, the I/O unit 1102 may implement other types of well-known interfaces for communicating with external devices.

The I/O unit 1102 decodes packets received via the interconnect 1118. In an embodiment, the packets represent commands configured to cause the parallel processing unit 1120 to perform various operations. The I/O unit 1102 transmits the decoded commands to various other units of the parallel processing unit 1120 as the commands may specify. For example, some commands may be transmitted to the front-end unit 1104. Other commands may be transmitted to the hub 1106 or other units of the parallel processing unit 1120 such as one or more copy engines, a video encoder, a video decoder, a power management unit, etc. (not explicitly shown). In other words, the I/O unit 1102 is configured to route communications between and among the various logical units of the parallel processing unit 1120.

In an embodiment, a program executed by the host processor encodes a command stream in a buffer that provides workloads to the parallel processing unit 1120 for processing. A workload may comprise several instructions and data to be processed by those instructions. The buffer is a region in a memory that is accessible (e.g., read/write) by both the host processor and the parallel processing unit 1120. For example, the I/O unit 1102 may be configured to access the buffer in a system memory connected to the interconnect 1118 via memory requests transmitted over the interconnect 1118. In an embodiment, the host processor writes the command stream to the buffer and then transmits a pointer to the start of the command stream to the parallel processing unit 1120. The front-end unit 1104 receives pointers to one or more command streams. The front-end unit 1104 manages the one or more streams, reading commands from the streams and forwarding commands to the various units of the parallel processing unit 1120.

The front-end unit 1104 is coupled to a scheduler unit 1108 that configures the various general processing cluster 1122 modules to process tasks defined by the one or more streams. The scheduler unit 1108 is configured to track state information related to the various tasks managed by the scheduler unit 1108. The state may indicate which processing cluster 1122 a task is assigned to, whether the task is active or inactive, a priority level associated with the task, and so forth. The scheduler unit 1108 manages the execution of a plurality of tasks on the one or more processing cluster 1122 modules.

The scheduler unit 1108 is coupled to a work distribution unit 1110 that is configured to dispatch tasks for execution on the processing cluster 1122 modules. The work distribution unit 1110 may track a number of scheduled tasks received from the scheduler unit 1108. In an embodiment, the work distribution unit 1110 manages a pending task pool and an active task pool for each of the processing cluster 1122 modules. The pending task pool may comprise a number of slots (e.g., 32 slots) that contain tasks assigned to be processed by a particular processing cluster 1122. The active task pool may comprise a number of slots (e.g., 4 slots) for tasks that are actively being processed by the processing cluster 1122 modules. As a processing cluster 1122 finishes the execution of a task, that task is evicted from the active task pool for the processing cluster 1122 and one of the other tasks from the pending task pool is selected and scheduled for execution on the processing cluster 1122. If an active task has been idle on the processing cluster 1122, such as while waiting for a data dependency to be resolved, then the active task may be evicted from the processing cluster 1122 and returned to the pending task pool while another task in the pending task pool is selected and scheduled for execution on the processing cluster 1122.

The work distribution unit 1110 communicates with the one or more processing cluster 1122 modules via crossbar 1114. The crossbar 1114 is an interconnect network that couples many of the units of the parallel processing unit 1120 to other units of the parallel processing unit 1120. For example, the crossbar 1114 may be configured to couple the work distribution unit 1110 to a particular processing cluster 1122. Although not shown explicitly, one or more other units of the parallel processing unit 1120 may also be connected to the crossbar 1114 via the hub 1106.

The tasks are managed by the scheduler unit 1108 and dispatched to a processing cluster 1122 by the work distribution unit 1110. The processing cluster 1122 is configured to process the task and generate results. The results may be consumed by other tasks within the processing cluster 1122, routed to a different processing cluster 11220 via the crossbar 1114, or stored in the memory 1112. The results can be written to the memory 1112 via the memory partition unit 1124 modules, which implement a memory interface for reading and writing data to/from the memory 1112. The results can be transmitted to another parallel processing unit 1120 or CPU via the NVLink 1116. In an embodiment, the parallel processing unit 1120 includes a number U of memory partition unit 1124 modules that is equal to the number of separate and distinct memory 1112 devices coupled to the parallel processing unit 1120.

In an embodiment, a host processor executes a driver kernel that implements an application programming interface (API) that enables one or more applications executing on the host processor to schedule operations for execution on the parallel processing unit 1120. In an embodiment, multiple compute applications are simultaneously executed by the parallel processing unit 1120 and the parallel processing unit 1120 provides isolation, quality of service (QoS), and independent address spaces for the multiple compute applications. An application may generate instructions (e.g., API calls) that cause the driver kernel to generate one or more tasks for execution by the parallel processing unit 1120. The driver kernel outputs tasks to one or more streams being processed by the parallel processing unit 1120. Each task may comprise one or more groups of related threads, referred to herein as a warp. In an embodiment, a warp comprises 32 related threads that may be executed in parallel. Cooperating threads may refer to a plurality of threads including instructions to perform the task and that may exchange data through shared memory.

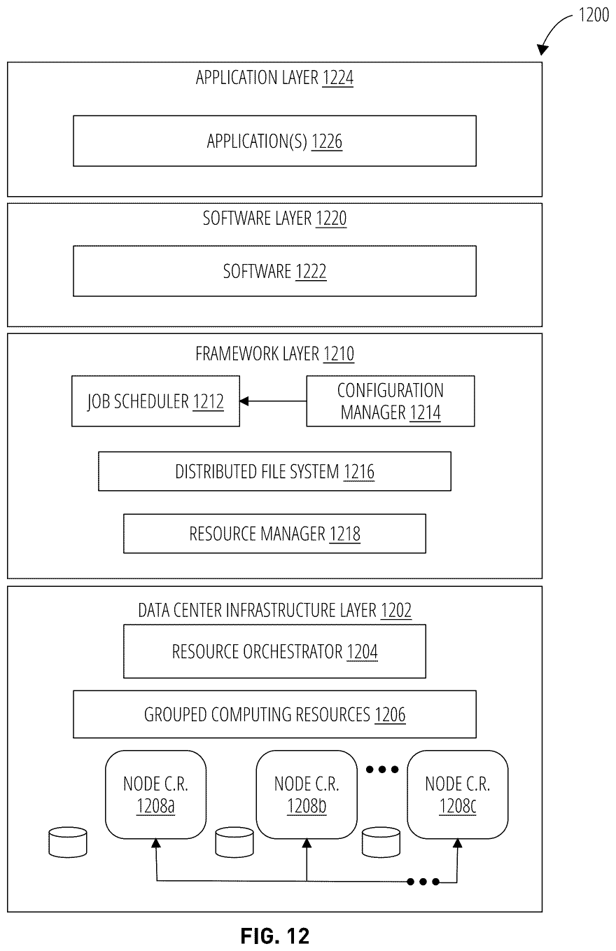

FIG. 12 depicts an exemplary data center 1200, in accordance with at least one embodiment. In at least one embodiment, data center 1200 includes, without limitation, a data center infrastructure layer 1202, a framework layer 1210, a software layer 1220, and an application layer 1224.

In at least one embodiment, as depicted in FIG. 12, data center infrastructure layer 1202 may include a resource orchestrator 1204, grouped computing resources 1206, and node computing resources (node C.R.s) 1208a-1208c, where “N” represents any whole, positive integer. In at least one embodiment, node computing resources may include, but are not limited to, any number of central processing units (CPUs) or other processors (including accelerators, field programmable gate arrays (FPGAs), graphics processors, etc.), memory devices (e.g., dynamic read-only memory), storage devices (e.g., solid state or disk drives), network input/output (NW I/O) devices, network switches, virtual machines (VMs), power modules, and cooling modules, etc. These components may communicate for example using transceivers in accordance with the exemplary embodiments disclosed herein. In at least one embodiment, one or more node computing resources from among node computing resources 1208a-1208c may be a server having one or more of the above-mentioned computing resources.

In at least one embodiment, grouped computing resources 1206 may include separate groupings of node computing resources housed within one or more racks (not shown), or many racks housed in data centers at various geographical locations (also not shown). Separate groupings of node computing resources within grouped computing resources 1206 may include grouped compute network, memory, or storage resources that may be configured or allocated to support one or more workloads. In at least one embodiment, several node computing resources including CPUs or processors may be grouped within one or more racks to provide compute resources to support one or more workloads. In at least one embodiment, one or more racks may also include any number of power modules, cooling modules, and network switches, in any combination.

In at least one embodiment, resource orchestrator 1204 may configure or otherwise control one or more node computing resources 1208a-1208c and/or grouped computing resources 1206. In at least one embodiment, resource orchestrator 1204 may include a software design infrastructure (“SDI”) management entity for data center 1200. In at least one embodiment, resource orchestrator 1204 may include hardware, software, or some combination thereof.

In at least one embodiment, as depicted in FIG. 12, framework layer 1210 includes, without limitation, a job scheduler 1212, a configuration manager 1214, a resource manager 1218, and a distributed file system 1216. In at least one embodiment, framework layer 1210 may include a framework to support software 1222 of software layer 1220 and/or one or more application(s) 1226 of application layer 220. In at least one embodiment, software 1222 or application(s) 1226 may respectively include web-based service software or applications, such as those provided by Amazon Web Services, Google Cloud, and Microsoft Azure. In at least one embodiment, framework layer 1210 may be, but is not limited to, a type of free and open-source software web application framework such as Apache SPARKTM (hereinafter “Spark) that may utilize a distributed file system 1216 for large-scale data processing (e.g., “big data”). In at least one embodiment, job scheduler 1212 may include a Spark driver to facilitate scheduling of workloads supported by various layers of data center 1200. In at least one embodiment, configuration manager 1214 may be capable of configuring different layers such as software layer 1220 and framework layer 1210, including Spark and distributed file system 1216 for supporting large-scale data processing. In at least one embodiment, resource manager 1218 may be capable of managing clustered or grouped computing resources mapped to or allocated for support of distributed file system 1216 and job scheduler 1212. In at least one embodiment, clustered or grouped computing resources may include grouped computing resources 1206 at data center infrastructure layer 1202. In at least one embodiment, resource manager 1218 may coordinate with resource orchestrator 1204 to manage these mapped or allocated computing resources.

In at least one embodiment, software 1222 included in software layer 1220 may include software used by at least portions of node computing resources 1208a-1208c, grouped computing resources 1206, and/or distributed file system 1216 of framework layer 1210. One or more types of software may include, but are not limited to, Internet web page search software, e-mail virus scan software, database software, and streaming video content software.

In at least one embodiment, application(s) 1226 included in application layer 1224 may include one or more types of applications used by at least portions of node computing resources 1208a-1208c, grouped computing resources 1206, and/or distributed file system 1216 of framework layer 1210. In at least one or more types of applications may include, without limitation, Compute Unified Device Architecture (CUDA) applications, 5G network applications, artificial intelligence applications, data center applications, and/or variations thereof.

In at least one embodiment, any of configuration manager 1214, resource manager 1218, and resource orchestrator 1204 may implement any number and type of self-modifying actions based on any amount and type of data acquired in any technically feasible fashion. In at least one embodiment, self-modifying actions may relieve a data center operator of data center 1200 from making possibly bad configuration decisions and possibly avoiding underutilized and/or poorly performing portions of a data center.

### LISTING OF DRAWING ELEMENTS

102 line driver
202 P-over-N line driver
402 level shifter
502 line driver
504 pull-up transistor
802 line driver
804 level shifter
902 line driver
904 capacitor
1002 line driver
1102 I/O unit
1104 front-end unit
1106 hub
1108 scheduler unit
1110 work distribution unit
1112 memory
1114 crossbar
1116 NVLink
1118 interconnect
1120 parallel processing unit
1122 processing cluster
1124 memory partition unit
1200 data center
1202 data center infrastructure layer
1204 resource orchestrator
1206 grouped computing resources
1208a node computing resource
1208b node computing resource
1208c node computing resource
1210 framework layer
1212 job scheduler
1214 configuration manager
1216 distributed file system
1218 resource manager
1220 software layer
1222 software
1224 application layer
1226 application(s)

Various functional operations described herein may be implemented in logic that is referred to using a noun or noun phrase reflecting said operation or function. For example, an association operation may be carried out by an “associator” or “correlator”. Likewise, switching may be carried out by a “switch”, selection by a “selector”, and so on. “Logic” refers to machine memory circuits and non-transitory machine readable media comprising machine- executable instructions (software and firmware), and/or circuitry (hardware) which by way of its material and/or material-energy configuration comprises control and/or procedural signals, and/or settings and values (such as resistance, impedance, capacitance, inductance, current/voltage ratings, etc.), that may be applied to influence the operation of a device. Magnetic media, electronic circuits, electrical and optical memory (both volatile and nonvolatile), and firmware are examples of logic. Logic specifically excludes pure signals or software per se (however does not exclude machine memories comprising software and thereby forming configurations of matter). Logic symbols in the drawings should be understood to have their ordinary interpretation in the art in terms of functionality and various structures that may be utilized for their implementation, unless otherwise indicated.

Within this disclosure, different entities (which may variously be referred to as “units,” “circuits,” other components, etc.) may be described or claimed as “configured” to perform one or more tasks or operations. This formulation-[entity] configured to [perform one or more tasks]-is used herein to refer to structure (i.e., something physical, such as an electronic circuit). More specifically, this formulation is used to indicate that this structure is arranged to perform the one or more tasks during operation. A structure can be said to be “configured to” perform some task even if the structure is not currently being operated. A “credit distribution circuit configured to distribute credits to a plurality of processor cores” is intended to cover, for example, an integrated circuit that has circuitry that performs this function during operation, even if the integrated circuit in question is not currently being used (e.g., a power supply is not connected to it). Thus, an entity described or recited as “configured to” perform some task refers to something physical, such as a device, circuit, memory storing program instructions executable to implement the task, etc. This phrase is not used herein to refer to something intangible.

The term “configured to” is not intended to mean “configurable to.” An unprogrammed FPGA, for example, would not be considered to be “configured to” perform some specific function, although it may be “configurable to” perform that function after programming.

Reciting in the appended claims that a structure is “configured to” perform one or more tasks is expressly intended not to invoke 35 U.S.C. § 112(f) for that claim element. Accordingly, claims in this application that do not otherwise include the “means for” [performing a function] construct should not be interpreted under 35 U.S.C § 112(f).

As used herein, the term “based on” is used to describe one or more factors that affect a determination. This term does not foreclose the possibility that additional factors may affect the determination. That is, a determination may be solely based on specified factors or based on the specified factors as well as other, unspecified factors. Consider the phrase “determine A based on B.” This phrase specifies that B is a factor that is used to determine A or that affects the determination of A. This phrase does not foreclose that the determination of A may also be based on some other factor, such as C. This phrase is also intended to cover an embodiment in which A is determined based solely on B. As used herein, the phrase “based on” is synonymous with the phrase “based at least in part on.”

As used herein, the phrase “in response to” describes one or more factors that trigger an effect. This phrase does not foreclose the possibility that additional factors may affect or otherwise trigger the effect. That is, an effect may be solely in response to those factors, or may be in response to the specified factors as well as other, unspecified factors. Consider the phrase “perform A in response to B.” This phrase specifies that B is a factor that triggers the performance of A. This phrase does not foreclose that performing A may also be in response to some other factor, such as C. This phrase is also intended to cover an embodiment in which A is performed solely in response to B.

As used herein, the terms “first,” “second,” etc. are used as labels for nouns that they precede, and do not imply any type of ordering (e.g., spatial, temporal, logical, etc.), unless stated otherwise. For example, in a register file having eight registers, the terms “first register” and “second register” can be used to refer to any two of the eight registers, and not, for example, just logical registers 0 and 1.

When used in the claims, the term “or” is used as an inclusive or and not as an exclusive or. For example, the phrase “at least one of x, y, or z” means any one of x, y, and z, as well as any combination thereof.

As used herein, a recitation of “and/or” with respect to two or more elements should be interpreted to mean only one element, or a combination of elements. For example, “element A, element B, and/or element C” may include only element A, only element B, only element C, element A and element B, element A and element C, element B and element C, or elements A, B, and C. In addition, “at least one of element A or element B” may include at least one of element A, at least one of element B, or at least one of element A and at least one of element B. Further, “at least one of element A and element B” may include at least one of element A, at least one of element B, or at least one of element A and at least one of element B.

The subject matter of the present disclosure is described with specificity herein to meet statutory requirements. However, the description itself is not intended to limit the scope of this disclosure. Rather, the inventors have contemplated that the claimed subject matter might also be embodied in other ways, to include different steps or combinations of steps similar to the ones described in this document, in conjunction with other present or future technologies. Moreover, although the terms “step” and/or “block” may be used herein to connote different elements of methods employed, the terms should not be interpreted as implying any particular order among or between various steps herein disclosed unless and except when the order of individual steps is explicitly described.

Having thus described illustrative embodiments in detail, it will be apparent that modifications and variations are possible without departing from the scope of the invention as claimed. The scope of inventive subject matter is not limited to the depicted embodiments but is rather set forth in the following Claims.

What is claimed is:

1. A circuit for communicating a signal over a first line, the circuit comprising:
a transmitter configured to generate the signal in a first voltage domain;
a first line driver comprising:
a P-over-N driver configured to receive the signal in the first voltage domain and to output the signal on the first line in a second voltage domain; and
a feed-forward pull-up transistor coupled to the first line.

2. The circuit of claim 1, further comprising:
a receiver configured to receive the signal in the second voltage domain.

3. The circuit of claim 2, wherein the receiver is configured to operate in the second voltage domain.

4. The circuit of claim 3, the receiver comprising an inverter-based topology.

5. The circuit of claim 4, the transmitter further comprising a level shifter coupled to the inverter-based topology via a second line.

6. The circuit of claim 5, the level shifter configured to shift a voltage of the signal from the second voltage domain to the first voltage domain.

7. The circuit of claim 2, wherein the receiver is configured to operate in a third voltage domain.

8. The circuit of claim 2, wherein the transmitter is part of a first chip and the receiver is part of a second chip.

9. A circuit for serial communication of signals over a line, the circuit comprising:
a transmitter configured to generate the signal in a first voltage domain;
a driver circuit for the line comprising:
a PFET pull-up path and NFET pull-up path arranged in parallel to a second voltage domain; and
a PFET feed-forward path for the signals configured to boost a transition of the signals from lower to higher voltage levels on the line.

10. The circuit of claim 9, further comprising:
a receiver configured to receive the signals in the second voltage domain.

11. The circuit of claim 10, wherein the receiver is configured to operate in the second voltage domain.

12. The circuit of claim 11, the receiver comprising an inverter-based topology.

13. The circuit of claim 12, the transmitter further comprising a level shifter coupled to the inverter-based topology.

14. The circuit of claim 13, the level shifter configured to shift a voltage of the signal from the second voltage domain to the first voltage domain.

15. The circuit of claim 10, wherein the receiver is configured to operate in a third voltage domain.

16. The circuit of claim 10, wherein the transmitter is part of a first chip and the receiver is part of a second chip.

17. A transceiver circuit comprising:
a transmitter in a first voltage domain AC-coupled to a receiver in a second voltage domain over a line;
one of an N-over-N driver and P-over-N driver for the line in a third voltage domain, the N-over-N driver or P-over-N driver configured to receive a signal in a first voltage domain of the transmitter and to output the signal on the line in the third voltage domain; and
the receiver comprising a pair of inverter stages arranged along the line, with negative feedback to a first inverter stage of the pair and positive feedback to both inverter stages.

18. The transceiver circuit of claim 17, wherein the transmitter is AC-coupled to the receiver via a capacitor that is proximity biased toward the receiver on the line.
